(19) United States
(12) Patent Application Publication
(10) Pub. No.: US 2020/0166586 A1
(43) Pub. Date: May 28, 2020

(54) DYNAMIC RANGE MODULE, SYSTEM AND METHOD

(71) Applicant: QUINC.TECH INC., San Diego, CA (US)

(72) Inventor: Lee LEMAY, San Diego, CA (US)

(21) Appl. No.: 16/592,746

(22) Filed: Oct. 3, 2019

Related U.S. Application Data
(60) Provisional application No. 62/740,672, filed on Oct. 3, 2018.

(51) Int. Cl. G01R 33/035; H03K 3/38

(52) U.S. Cl. CPC G01R 33/0356; H03K 3/38

(57) ABSTRACT

Aspects of the present disclosure relate to a dynamic range module, system and method in general. Aspects of the present disclosure also apply to dynamic range module, system and method implemented into devices benefiting from dynamic range such as radios, radar, test and measurement equipment, and other signals receivers. The dynamic range module uses one or more superconducting quantum interference devices (SQUIDs) to increase the dynamic range of the system.

### CROSS-REFERENCE TO RELATED APPLICATIONS

This application claims priority to U.S. provisional patent application 62/740,672, filed Oct. 3, 2018 and entitled DYNAMIC RANGE MODULE, SYSTEM AND METHOD, the contents of which are incorporated herein by reference in its entirety.

### BACKGROUND OF THE INVENTION

### Technical Field

The present disclosure generally pertains to mechanisms and methods for improving signal detection and amplification, and is more particularly directed towards mechanisms and methods for improving dynamic range in systems.

### Related Art

The present disclosure is generally intended to address a problem that arises when a system does not have enough dynamic range to detect signals of interest because of the presence of much stronger signals. This situation could occur when a radio is transmitting and receiving using the same bandwidth resource. In that situation, the radio's transmitted signal would be much stronger than received signal and would prevent the radio from detecting the much weaker received signals. Another situation where this could occur is in RADAR, where a strong return from clutter or jamming might mask a much weaker return from an object of interest. Another generalized situation is where a platform's own electronic emitters transmit extremely strong signals that disrupt the operation of the platform's other operational equipment.

As background, as used here, the dynamic range of a system is the ratio between the largest and smallest values of signal that a system can process. In electronics, the largest signal level is set by the amount of signal that causes the system to behave in a non-linear fashion. For example, amplifiers are often characterized by their 1 dB compression point—the amount of input power that will cause a 1 dB non-linearity in their output. An analog to digital convertor (ADC) can only digitize signals that are lower than their reference voltage—a signal that is higher than the reference voltage will be measured as equal to the reference voltage. The smallest detectable signal may be set by the least significant bit (LSB) of the ADC—anything that is smaller than the LSB is recorded as zero. Thus, in many systems, the dynamic range of the system is set by the ratio of the ADC's voltage reference to its LSB.

The dynamic range of a system is important any time there is that a strong signal is present at the same time as a much weaker signal of interest. For example, in radios, the ability to transmit and receive data at the same time and on the same frequency is limited in part by the dynamic range of the receiver's ADC. This is called operating in full duplex mode. Operating in full duplex, the transmitted signal will be much more powerful than the received signal. This strong signal can saturate the ADC or cause the automatic gain control circuit to increase the value of the ADC's LSB, which makes it difficult to measure the weaker signals. If the radio had enough dynamic range to operate in full duplex it would be twice as efficient in its use of spectrum.

Currently, when a strong signal is present, an automatic gain control circuit is used to decrease the gain of the signal processing chain. This has the advantage of preventing the strong signal from creating distortion, but it has the disadvantage that decreasing the gain means that the system cannot resolve weaker signals. To illustrate, in a simple system expecting to “see” signals of 1-10 units, when a signal of 12 is received, the automatic gain control may make 12 the new 10, and the old 1 may become 0.8, and thus be truncated to 0 (i.e., dropped off or otherwise lost).

One type of solution is to use multiple analog to digital convertors to cover a wider range. In particular, multiple analog to digital convertors interleave their sample clocks to increase the sample rate of a system. As such, the samples can then be averaged, which increases the dynamic range of the system. This approach may increase the dynamic range of a system by a factor of N in the ideal case, where N is the number of ADCs and ADC processing chains. Unfortunately, interleaving ADCs often cannot provide enough dynamic range without unreasonable complexity and expense. For example, if an application required a factor of 100 increase in dynamic range, this approach would require the precise interleaving of 100 ADCs, which would be expensive and prone to error.

In some instances, if the strong signals are well known, they can be subtracted out from the system. For example, in a radio that is transmitting and receiving using the same bandwidth resource, a copy of the transmitted signal can be subtracted from receive processing chain. This can significantly reduce the strength of the radio's transmitted signal at the radio's receiver, but it cannot completely remove the signal. Furthermore, this method requires additional components and complexity, which scales exponentially with the number of transmitters and receivers in a radio.

More particularly, and with regard to automatic gain control, in the past, the dynamic range of a system was set by the dynamic range of its components. When a signal that is being processed exceeds the maximum value of the processing system, the signal becomes distorted. One way that the signal may become distorted is by saturating the ADC, which results in clipping of large signals. To avoid distortion in a system that is attempting to measure a signal, an automatic gain control (AGC) circuit is used, which keeps the signal from distorting by decreasing the gain of the processing chain. When the AGC decreases the gain, the ADC resolution decreases, so quantization noise increases and interferes with smaller signals. In the past it has been challenging to sense very small signals and very large signals at the same time.

Likewise, and with regard to multiple ADCs, in the past, it has been possible to interleave multiple ADCs to increase the sample rate of a system. The samples may then be averaged, which increases the dynamic range of the system. This approach can increase the dynamic range of a system by a factor of N in the ideal case, where N is the number of ADCs and ADC processing chains. Interleaving ADCs often cannot provide enough dynamic range without unreasonable complexity and expense. For example, if an application required a factor of 100 increase in dynamic range, this approach would require the precise interleaving of 100 ADCs, which would be expensive and prone to error.

Likewise, and with regard to full duplex radio techniques, in the past, radiofrequency transceivers used several techniques to perform full-duplex (FD) transmission of a signal. For a radio, FD operation means that the radio transmits using the same bandwidth resources as it uses to receive a signal. Using a half-duplex scheme means that the radio uses separate bandwidth resources to transmit and receive a signal. Enabling FD will allow reuse of the same bandwidth resource, and result in greater throughput and higher spectral efficiency than a half-duplex (HD) configuration. The challenge with implementing FD is that the transmitted signal is much more powerful than the received signal, and results in significant self-interference. For FD to be possible the transmitted signal must be significantly reduced in the receiver processing chain. The techniques used to do this include passive techniques, active analog techniques, and digital techniques.

The passive techniques of reducing the transmitted signal at the receiver in an FD radio include physically separating the transmit and receive antenna, isolating the antennas using shielding, or using multiple transmit antennas and placing the receive antenna at a spot where the signals destructively interfere. These techniques have drawbacks, including that they increase the size of the transceiver, reduce the ability to estimate the transmit channel, impose narrow bandwidths, and require additional antennas.

Active analog techniques to reduce self-interference attempt to remove the transmitted signal in the receive signal analog processing chain. This is done by creating a copy of the transmitted signal and processing it so that when it is added to the received signal in the receive signal analog processing chain it attenuates the transmitted signal. Active analog techniques to cancel self-interference introduce complexity into the receiver's analog processing chain.

Cancellation in the digital domain is implemented by removing the transmitted signal from the received signal after the signal has been digitized. While it is relatively simple to implement, it is limited by the finite dynamic range of the ADC. Therefore, a combination of passive and active analog self-interference cancellation techniques is used before digitizing the signal.

Using current approaches, even with the combination of passive, active analog, and digital techniques, FD radios with large bandwidths and high transmit powers cannot be realized.

U.S Pat. App. Pub. No. 2017/0146618 by Leese de Escobar, et al. and published on May 25, 2017, shows a system and method for broadband far and near field radio frequency radiation detection using superconducting quantum detector arrays. The system and method relate to an antenna includes a plurality of superconducting quantum interference device (SQUID) arrays on a chip, and a printed circuit board (PCB) formed with a cutout for receiving the chip. The PCB is formed with a set of coplanar transmission lines, and the chip is inserted into the cutout so that each said transmission line connects to a respective SQUID array. A cryogenic system can cool the chip to a temperature that causes a transition to superconductivity for the SQUID arrays. A thermal radome can be placed around the chip, the PCB and the cryogenic system to maintain the temperature. A DC bias can be applied to the SQUID arrays to facilitate RF detection. The SQUID array, chip and CPW transmission lines can cooperate to allow for both detection of said RF energy and conversion of said RF energy to a signal without requiring the use of a conductive antenna dish.

The present disclosure is directed toward overcoming known problems and problems discovered by the inventor.

### SUMMARY OF THE INVENTION

Aspects of the present disclosure relate to a dynamic range module, system and method in general. Aspects of the present disclosure also apply to dynamic range module, system and method implemented into devices benefiting from dynamic range such as radios, radar, test and measurement equipment, and other signals receivers. The dynamic range module uses one or more superconducting quantum interference devices (SQUIDs) to increase the dynamic range of the system.

A dynamic range module for a signal receiver is disclosed herein. The signal receiver has an analog front end including a signal carrying conductor, an automatic gain control (AGC) having a minimum and maximum boundary voltage, and a signal processing back end. The dynamic range module a superconducting quantum interference device (SQUID) configured to sense at least a portion of magnetic fields created by an electric signal travelling along the signal carrying conductor, said electric signal having combined together at least a first analog signal at a first power level and a second analog signal at a second power level, the first power level sufficiently greater than the second power level to require the AGC of the signal receiver to scale the electric signal to be within the minimum and maximum boundary voltage, the SQUID having a critical temperature; and circuitry configured to decouple the first analog signal at the first power level from the second analog signal at the second power level and communicate both the first analog signal and the second analog signal to the signal processing back end of the signal receiver within the minimum and maximum boundary voltage.

According to one embodiment, a signal receiver is disclosed herein. The signal receiver includes an analog front end including a signal carrying conductor; an automatic gain control (AGC) having a minimum and maximum boundary voltage; a signal processing back end; a superconducting quantum interference device (SQUID) configured to sense at least a portion of magnetic fields created by an electric signal travelling along the signal carrying conductor, said electric signal having combined together at least a first analog signal at a first power level and a second analog signal at a second power level, the first power level sufficiently greater than the second power level to require the AGC of the signal receiver to scale the electric signal to be within the minimum and maximum boundary voltage, the SQUID having a critical temperature; a cryogenic system configured to cool the SQUID to or below the critical temperature; and circuitry configured to decouple the first analog signal at the first power level from the second analog signal at the second power level and communicate both the first analog signal and the second analog signal to the signal receiver within the minimum and maximum boundary voltage.

According to one embodiment, a transducer system is disclosed herein. The transducer system includes an analog front end including a signal carrying conductor; an automatic gain control (AGC) having a minimum and maximum boundary voltage; a signal processing back end; a superconducting quantum interference device (SQUID) configured to sense at least a portion of magnetic fields created by an electric signal travelling along the signal carrying conductor, said electric signal having combined together at least a first analog signal at a first power level and a second analog signal at a second power level, the first power level sufficiently greater than the second power level to require the AGC of the signal receiver to scale the electric signal to be within the minimum and maximum boundary voltage, the SQUID having a critical temperature; a cryogenic system configured to cool the SQUID to or below the critical temperature; and circuitry configured to decouple the first analog signal at the first power level from the second analog signal at the second power level and communicate both the first analog signal and the second analog signal to the signal receiver within the minimum and maximum boundary voltage.

### BRIEF DESCRIPTION OF THE DRAWINGS

FIG. 1 shows a RCSJ model with current noise for a Josephson Junction (JJ). The JJ, denoted by an ‘x’ intersecting a line, is on the left, and the RCSJ model is on the right. The quantity δ is the gauge invariant phase difference across the junction.

FIG. 2 shows a DC SQUID approximated using the RCSJ model. The DC SQUID is denoted as a loop with two Josephson Junctions. The inductance LL is the inductance of the superconducting loop, which is made up of both geometric and kinetic inductances.

FIG. 3 shows a DC SQUID with magnetic flux lines.

FIG. 4 shows a voltage response of a SQUID as a function of the applied magnetic field. The voltage response is periodic with respect to the applied magnetic field, with a period equal to one flux quantum.

FIG. 5 schematically illustrates a radio incorporating a dynamic range module according to one exemplary embodiment of the present disclosure.

FIG. 6 schematically illustrates a radio incorporating a dynamic range module according to another exemplary embodiment of the present disclosure.

FIG. 7 schematically illustrates a radio incorporating a dynamic range module according to yet another exemplary embodiment of the present disclosure.

FIG. 8 schematically illustrates components of a linearization system, according to one exemplary embodiment of the present disclosure.

FIG. 9 schematically illustrates components of a dynamic range module, according to one exemplary embodiment of the present disclosure.

FIG. 10 schematically illustrates components of a linearization system including switching to provide for the linearization system to be dis-engaged and re-engaged, according to one exemplary embodiment of the present disclosure.

FIG. 11 shows a voltage response vs. magnetic field of a SQUID with a resettable flux locked loop producing linearized outputs.

FIG. 12 schematically illustrates a dynamic range module containing N devices, according to one exemplary embodiment of the present disclosure.

FIG. 13 shows a voltage vs magnetic field for SQUIDs with different effective areas.

FIG. 14 shows an input field to the SQUID and output of the FLL together, according to one embodiment of the present disclosure.

FIG. 15 is a process diagram of the combination of channels during reset periods.

FIG. 16 schematically illustrates a dynamic range module in a radiofrequency receiver consisting of two SQUIDs with FLL circuits.

### DETAILED DESCRIPTION

Aspects of the present disclosure relate to a dynamic range module, system and method in general. Aspects of the present disclosure also apply to the dynamic range module, system and method being implemented into devices benefiting from dynamic range such as radios, radar, signals receivers, or test and measurement equipment. The dynamic range module uses one or more superconducting quantum interference devices (SQUIDs) to increase the dynamic range of the system. The disclosure relates to measuring and processing signals, and more particularly to increasing the ratio of a maximum signal to a minimum signal that a system can process.

Any device that produces an output signal that is periodic with respect to an input signal can be used to create the dynamic range module. One example of a device that produces a response that is periodic with respect to its input is a superconducting quantum interference device (SQUID). A SQUID produces a voltage response that is periodic with respect to the applied magnetic field. Arrays of SQUIDs may also be used to create the dynamic range modules, as can SQUID-like devices, such as Bi-SQUIDs. The device may also contain flux focusing structures that change the periodicity of the device's voltage response vs applied magnetic field. In this document, “SQUID” refers to any superconducting device that contains at least one Josephson Junction and exhibits a voltage response that is periodic with respect to the applied magnetic field.

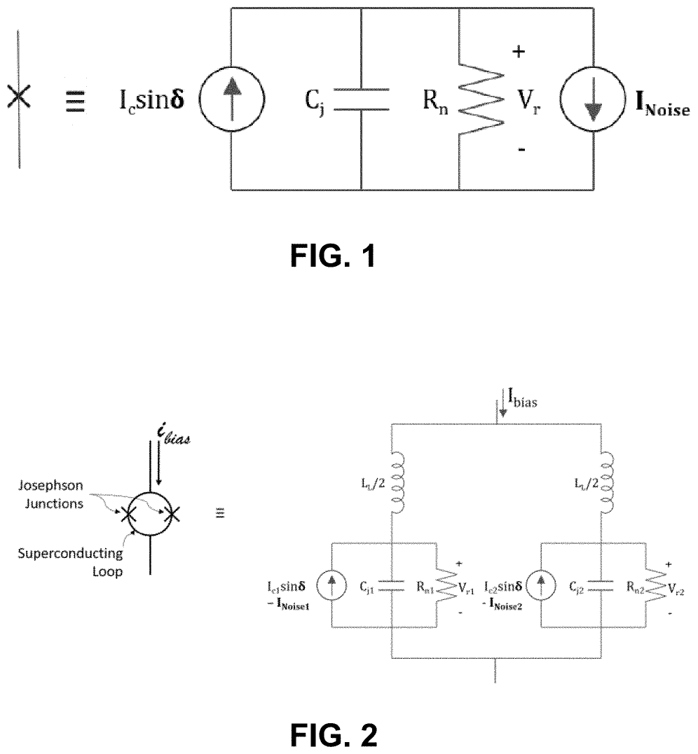

FIG. 1 shows a RCSJ model with current noise for a Josephson Junction (JJ). The JJ, denoted by an ‘x’ intersecting a line, is on the left, and the RCSJ model is on the right.

The quantity δ is the gauge invariant phase difference across the junction. Ic, Cj, and Rn in FIG. 1 are the critical current, junction capacitance, and the normal resistance of the junction. These electrical properties describe the behavior of the junction, and they are dependent upon the superconducting material and the junction layout and geometry.

FIG. 2 shows a DC SQUID approximated using the RCSJ model. The DC SQUID is denoted as a loop with two Josephson Junctions. The inductance LL is the inductance of the superconducting loop, which is made up of both geometric and kinetic inductances. Magnetic flux is quantized, meaning that it only exists in integer multiples of the magnetic flux quantum. The magnetic flux quantum is denoted as ϕ0, and is equal to h2e/, where h is Planck's constant and e is the elementary charge. φ0=h2e/≈2.067×10−15Wb.

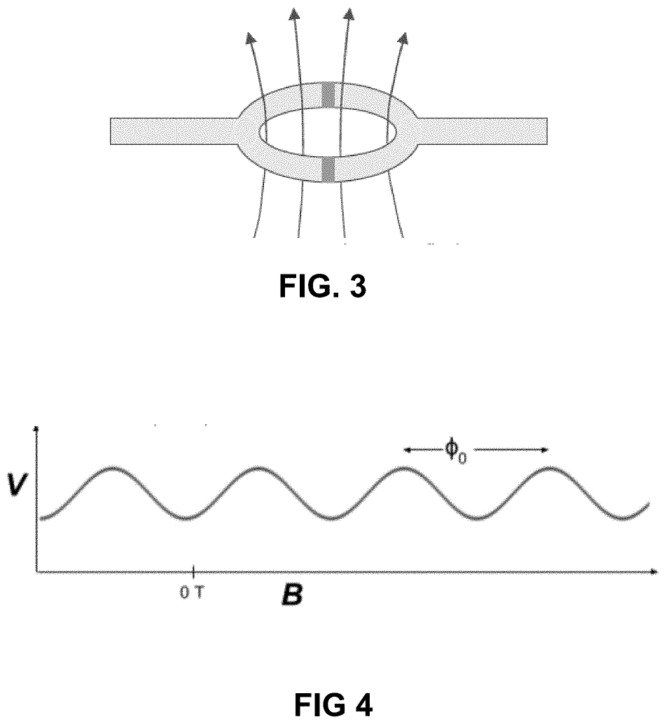

FIG. 3 shows a DC SQUID with magnetic flux lines. In particular, FIG. 3 shows magnetic flux passing through a SQUID. When magnetic flux passes through the SQUID, it must do so in integer multiples of the flux quantum. If the amount of flux passing through the SQUID does not equal an integer of the flux quantum, a screening current occurs in the SQUID to force the amount of flux to the nearest integer multiple of the flux quantum. When the current passes through the JJs, it alters the gauge invariant phase across the junction. This causes the frequency of the current that the JJs are producing to change. The signals from the two JJs interfere and create a voltage that varies periodically as a function of applied magnetic field. Put another way, a SQUID produces a periodic voltage as a function of the input magnetic field. Beneficially, this means that the SQUID will not saturate or induce distortion as the magnetic field increases.

FIG. 4 shows a voltage response of a SQUID as a function of the applied magnetic field. In particular, as the strength of the magnetic flux field moved on the x-axis, the voltage will oscillate between a maxima and a minima. Further, the voltage response is periodic with respect to the applied magnetic field, with a period equal to one flux quantum.

As above, as the field increases from zero Tesla, a screening current is set up to keep the flux that is passing through the SQUID at zero. As the field increases, the screening current increases, which results in a higher voltage. When the field increases further, the amount of flux passing through the SQUID is closer to one flux quanta than it is to zero flux quanta, and the direction of the screening current reverses. Then, as the field increases even further, the screening current decreases, until the flux passing through the SQUID from the applied magnetic field is exactly one flux quanta, and the screening current is zero. This cycle repeats as the field increases further, leading to a periodic voltage vs. magnetic field. The period of the SQUID's voltage response is equal to one flux quantum.

The inventor has discovered that a dynamic range module can be added to a system that will increase the ratio of the maximum signal to the minimum signal that a system can process. This ratio is called the dynamic range of the system. The dynamic range module is composed of one or more non-linear devices that each produce a signal that is periodic with respect to an input signal. Each device contains a linearization system that produces an output signal that is linearly proportional to the input signal. The linear transfer function output has a slope with respect to the input. The linearization system may be reset, or may reset automatically, to linearize the output of the device at a new point in its periodic output signal. Additional processing stages after the device can change the slope of the output signal with respect to the input signal. The transfer function of each device in the module, or of each device's processing stages, has a different slope. The device with the smallest slope has the least precise resolution.

A device with larger slope can measure portions of the signal with more precise resolution than a device with smaller slope. The device with the smallest slope can process the entire signal without causing saturating or distortion of the linearization system or of the downstream processing stages. For certain values of the input signal, devices with larger slopes will require their linearization system to reset to avoid saturation or distortion. By using multiple devices, each with different slopes, the total dynamic range can be divided into multiple channels, a coarse channel composed of the most significant bits, and successively finer channels composed of successively less significant bits. Each channel can then be processed independently. This relaxes the dynamic range requirements of components that follow the module and will expand the dynamic range of many systems.

According to one embodiment, an alternative method to resolve the ambiguity of the absolute value of input signal after the device re-linearizes at a new operating point is to create a processing path that contains no SQUIDs, which can be used to create a coarse measurement of the signal. This coarse measurement can then be used to resolve the ambiguity of the device with the most gradual transfer function, which can resolve the ambiguity of the device with the next steepest transfer function, and so on and so forth, until every device's measurement can be related to the signal's absolute value. Using this method, a Dynamic Range Module could be instantiated with a single SQUID, or with more than one SQUID. Using this method, an ideal dynamic range module with N devices can increase the dynamic range to the power of N+1.

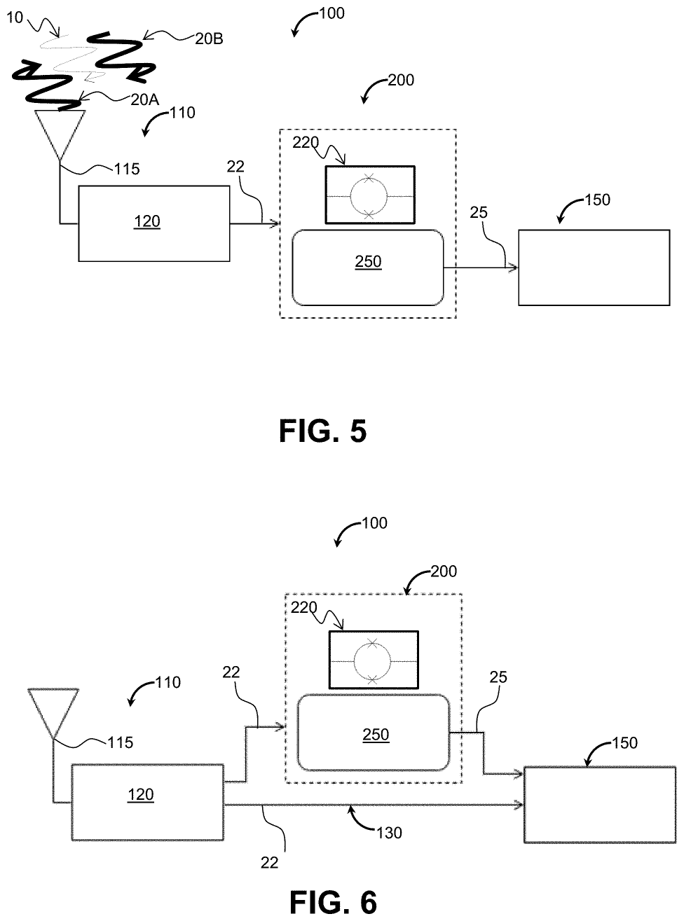

FIG. 5 schematically illustrates a radio incorporating a dynamic range module according to one exemplary embodiment of the present disclosure. As shown, a lower energy signal 10 may come into competition with at least one of an outbound higher power transmission 20A (e.g., full-duplex transmission) and an inbound higher power transmission 20B (e.g., RADAR jamming). The difference between the competing signals may cause the automatic gain control (AGC) of a conventional receiver to scale such that the weaker signal is clipped or otherwise lost. Here however, a dynamic range module, may be employed to address this.

As shown, a radio 100 may include a radio front end 110, a dynamic range module 200, and a signal processing back end 150. The radio 100 may be full duplex or half duplex. The radio front end 110 may include signal reception components such as an antenna 115 and other RF radio front end circuitry 120 (e.g., filters, mixers, oscillators, amplifiers, etc.). Similarly, the signal processing back end 150 may generally include components for modifying and/or using analog and digital signals (e.g., filters, amplifiers, ADCs, DACs, processors, etc.). The dynamic range module 200 may include one or more SQUID devices 220 and linearization circuitry 250 as discussed further herein.

As shown, the dynamic range module 200 may be integrated as a serial component of the radio 100 in the radio's receive path. In particular, the dynamic range module 200 may be communicably coupled in series with or otherwise interspersed between the radio front end 110 and the signal processing back end 150. In this arrangement, the dynamic range module 200 may sense a combined analog signal 22 (e.g., including the lower energy signal 10, and at least one of the outbound higher power transmission 20A and the inbound higher power transmission 20B), and then output decoupled signals 25 to the signal processing back end 150. The decoupled signals 25 may be provided to the signal processing back end 150, within the dynamic range of its components. Beneficially, this may limit the need for multiple ADCs or other corrective measures.

FIG. 6 schematically illustrates a radio incorporating a dynamic range module according to another exemplary embodiment of the present disclosure. In particular, the dynamic range module 200 is shown integrated as a parallel component of the radio 100, interspersed in the radio's receive path

As above, the radio 100 may include the radio front end 110 (including the antenna 115 and other RF radio front end circuitry 120), the dynamic range module 200 (including one or more SQUID devices 220 and linearization circuitry 250), and the signal processing back end 150. As shown, the dynamic range module 200 may be communicably coupled in parallel with an independent link 130 (i.e., a separate communication link such as a wire, carrier line, or other signal carrying conductor), between the radio front end 110 and the signal processing back end 150.

In this arrangement, the dynamic range module 200 may sense the combined analog signal 22 from the radio front end 110, and then output decoupled signals 25 to the signal processing back end 150. The decoupled signals 25 may be provided to the signal processing back end 150 within the dynamic range of its components, limiting the need for multiple ADCs. Alternately, the decoupled signals 25 may be pre-processed within linearization circuitry 250.

According to one embodiment, when the combined analog signal 22 falls within in limitations of the components of the signal processing back end 150 (e.g., the ADC), the dynamic range module 200 may be bypassed, using the independent link 130 directly. However, where the combined analog signal 22 falls outside in limitations of the components of the signal processing back end 150, the parallel path running through the dynamic range module 200 may be used, for example, as an exclusive, dominant, and/or fine tuning communication path.

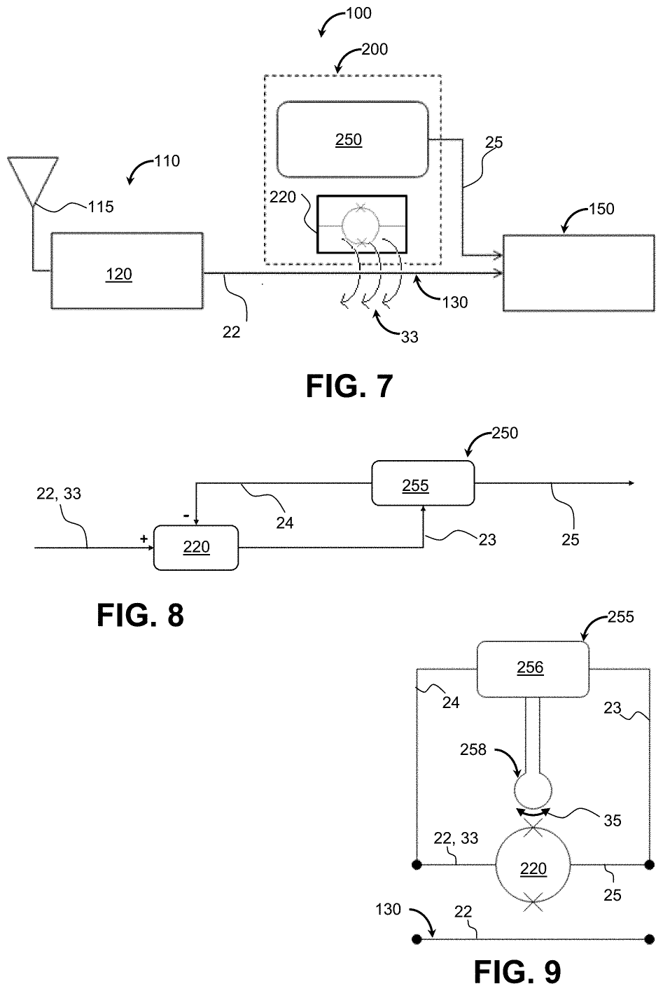

FIG. 7 schematically illustrates a radio incorporating a dynamic range module according to yet another exemplary embodiment of the present disclosure. In particular, the dynamic range module 200 is shown integrated as a parallel component of the radio 100, magnetically coupled with the radio's receive path.

As above, the radio 100 may include the radio front end 110 (including the antenna 115 and other RF radio front end circuitry 120), the dynamic range module 200 (including one or more SQUID devices 220 and linearization circuitry 250), and the signal processing back end 150. As shown, the dynamic range module 200 may be magnetically coupled in parallel with the independent link 130 between the radio front end 110 and the signal processing back end 150. In particular, the dynamic range module 200 may be configured to sense the resultant magnetic field 33 about the independent link 130 of the combined analog signal 22 traveling down the independent link 130.

In this arrangement, the dynamic range module 200 may again sense the combined analog signal 22 from the radio front end 110 (via the independent link 130), and then output decoupled signals 25 to the signal processing back end 150 within the dynamic range of its components. Also, the decoupled signals 25 may be pre-processed within linearization circuitry 250. Advantageously, in this embodiment, the dynamic range module 200 may be added to an existing architecture with minimal impact, and the decoupled signals 25 may be interpreted via a processor of the existing architecture (e.g., via a software/firmware modification) or a local processor of the linearization circuitry 250.

As above, when the combined analog signal 22 falls within in limitations of the components (e.g., the ADC) of the signal processing back end 150, the dynamic range module 200 may be bypassed, using the independent link 130 directly. However, where the combined analog signal 22 falls outside in limitations of the components of the signal processing back end 150, the dynamic range module 200 may be used, for example, as an exclusive, dominant, and/or fine tuning communication path.

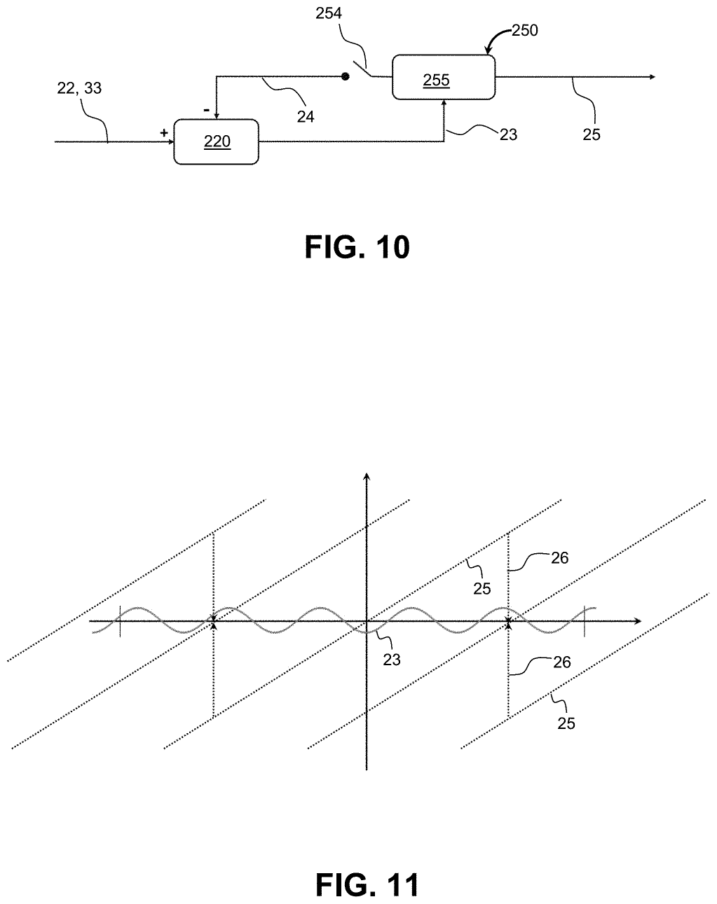

FIG. 8 schematically illustrates components of a linearization system, according to one exemplary embodiment of the present disclosure. FIG. 9 schematically illustrates components of a dynamic range module according to one exemplary embodiment of the present disclosure. FIG. 10 schematically illustrates components of a linearization system including switching to provide for the linearization system to be dis-engaged and re-engaged, according to one exemplary embodiment of the present disclosure.

As above, the dynamic range module 200 may include linearization circuitry 250. Generally, the linearization circuitry 250 may include a feedback loop 255 configured to convert a non-linear output signal 23 of the one or more SQUID devices 220 into a linear output signal (decoupled signals 25). The linearization circuitry 250 is broadly defined as including any required circuitry/processors to result in a feedback signal 24, and ultimately the decoupled signals 25, which here, are linearized and otherwise useable by the signal processing back end 150. According to one embodiment, the linearization circuitry 250 may further include switching 254 operable as an engage/disengage switch for the feedback signal 24.

A circuit called a Flux Locked Loop (FLL) uses negative feedback to linearize the output of the SQUID. When the FLL or the electronics that processes the SQUID's output saturates, the FLL can be reset. When the FLL is reset, it will linearize the SQUID's output at a new operating point.

According to one embodiment, the linearization circuitry 250 may include, but is not limited to, a magnetic field generator 258, flux locked loop electronics 256 and/or a local processor (not shown). In particular, the magnetic field generator 258 may be configured to generate magnetic flux that will interact with the one or more SQUID devices 220, causing or remapping the voltage output of the one or more SQUID devices 220 to be linear voltages, over a predefined field strength range of the sensed magnetic field 33.

The flux locked loop (FLL) electronics 256 may be configured to drive the magnetic field generator 258. For example, the magnetic field generator 258 may generally include a conductive loop proximate the one or more SQUID devices 220. The FLL electronics 256 may be configured to create a current 35 through the conductive loop of the magnetic field generator 258, such that a predetermined magnetic flux is passed through the SQUID device 220, which counteracts and thus linearizes the SQUID device 220 output.

Regarding flux locked loops, a feedback circuit called a flux locked loop (FLL) is used to linearize the output of a SQUID. The FLL applies a feedback flux that is opposite to the external flux to keep the amount of flux entering the SQUID constant. As the external flux increases or decreases, an amplifier drives the feedback circuit proportionally, creating a voltage response that is linearly proportional to the external flux. The FLL can be dis-engaged, allowing the device to experience only the external magnetic flux. The FLL can then be re-engaged, causing the feedback circuitry to oppose any new change in the external flux. In this way the device can be linearized at different values of the external magnetic field. This is referred to as “resetting” the FLL.

According to one embodiment, the linearization circuitry 250 may be configured to automatically reset the FLL without the need for any external circuitry to engage and dis-engage the FLL. One way to do this is to use an amplifier to drive the feedback flux. When the combined external flux and feedback flux passes through a period of the SQUID device's 220 periodic voltage vs. flux transfer function, the feedback flux that the amplifier generates will begin to decrease. This causes a positive feedback loop that drives the operating point to the next stable linearization point. Because the SQUID device 220 is now linearized at different values of the external magnetic field, this is also referred to as “resetting” the FLL.

Referring to FIG. 8, device similar in principle to an FLL could be used to linearize the output of a non-SQUID device that produces an output signal that is periodic with respect to an input signal. For this non-SQUID device, the linearization circuitry 250 can create a signal that opposes the input signal to linearize the non-SQUID's output. As the input signal increases or decreases, the feedback loop 255 is driven proportionally, creating a voltage response that is linearly proportional to the external signal (combined analog signal 22/magnetic field 33). The linearization system can be dis-engaged, allowing the device to experience only the external signal. The linearization circuitry 250 can then be re-engaged, causing the feedback loop 255 (via the magnetic field generator 258) to oppose any new change in the external signal.

Referring to FIG. 10, the linearization circuitry 250 can be dis-engaged and re-engaged using a switch or a transistor (switching 254). There are other possible methods to dis-engage and re-engage the linearization system, including modifying the behavior of the linearization circuitry 250. By dis-engaging and then re-engaging the I feedback loop 255, the decoupled signals 25 of the radio 100 can be linearized at different values of the combined analog signal 22. Similarly to an FLL, this is referred to as “resetting”.

A non-SQUID linearization system can also be designed to automatically reset, without using any additional circuitry. This could be realized in a similar manner to the SQUID FLL, by having the external signal and the feedback signal pass through a period in the device's periodic transfer function, thereby causing a negative feedback signal to become a positive feedback signal. This positive feedback signal 24 drives the circuit to a new operating point where the feedback is negative again.

The linearization circuitry 250 of a SQUID 220 (or non-SQUID device) will have a transfer function that relates the output to the input. The transfer function will have a slope of that is defined as ∂O/∂I, where ∂O is the change in the output, and ∂I is the change in the input. The slope of the linearization system transfer function does not change when the linearization system is reset.

FIG. 11 shows a voltage response vs. magnetic field of a SQUID with a resettable flux locked loop producing linearized outputs. In particular, shown is the voltage response of the SQUID vs. the applied magnetic field, with an FLL linearizing its output. It also shows how the FLL can be reset to begin linearizing at a new point. Here, the non-linear output signal 23 is SQUID's voltage output without the FLL, which is represented as an oscillating line. Also, the decoupled signals 25 are represented by the diagonal dashed lines, which likewise represent the FLL output. The vertical dashed lines represent FLL resets 26, where the FLL is reset.

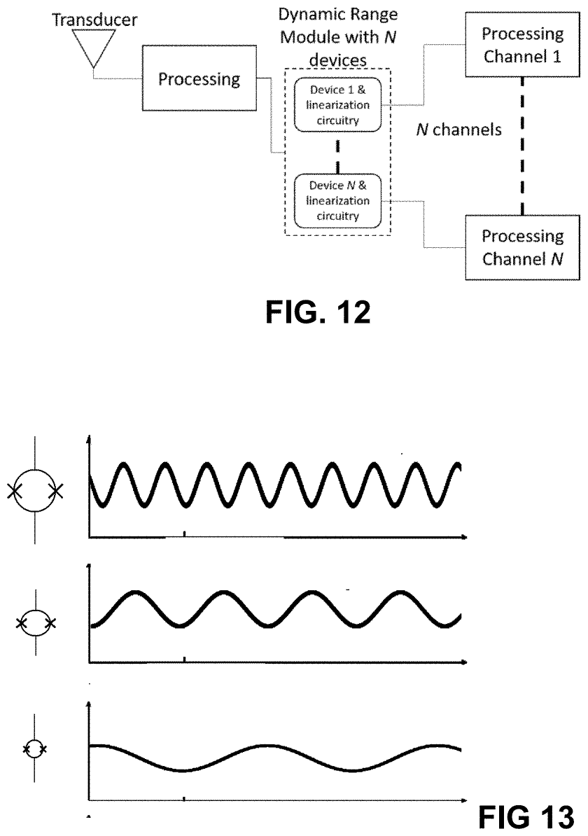

FIG. 12 schematically illustrates a dynamic range module containing N devices, producing N channels, connected to a transducer and processing subsystems. N is an integer 1 or greater. Further, the dynamic range module containing N devices could be connected to a generic transducer to split the dynamic range into N channels. In particular, shown here is a dynamic range module containing N devices, producing N channels, connected to a transducer and processing subsystems. N is an integer of 1 or greater than 1. To illustrate, a device that produces an output signal that is periodic with respect to an input signal can reset its linearization circuitry. This can be done instead of saturating or introducing distortions when the input signal exceeds the dynamic range of the device or the dynamic range of the components that are downstream of the device. When the device does this, it then re-linearizes at a new operating point and can continue to produce a linearized output that has the same slope of its output with respect to its input as it had before it reset.

When the device re-linearizes at a new operating point the absolute value of the input signal that it is processing is ambiguous. A cascade of these devices can resolve this ambiguity, where the linearized output of each device, ∂O/∂I, has a transfer function with a different slope; the steeper the slope of the transfer function, the finer the resolution of the device, and the more resets it will require to avoid saturation or distortion for a given signal. The linearized output of the device with the most gradual transfer function should be designed to be able to process the entire signal without resetting. In this way the device with the most gradual transfer function can resolve the ambiguity of the device with the next steepest transfer function, which can resolve the ambiguity of the device with the next steepest transfer function, and so on and so forth, until every device's measurement can be related to the signal's absolute value. Together, the devices in the cascade can make measurements with an extended dynamic range. An ideal dynamic range module with N devices can increase the dynamic range to the power of N.

Practically, a system including the dynamic range module will have the lower limit to its resolvable signal set by the slew rate of the signal; the ADC must have time to take a sample before the device resets. Slew rate is set by the signal amplitude and the signal frequency. Thus, a practically realized dynamic range module will deliver a dynamic range that decreases with signal frequency and signal amplitude. The delivered dynamic range increases with ADC sampling rates and ADC dynamic range.

In the case where the dynamic range module is realized using SQUIDs the magnetic field could be generated by a wire that is routed next to the devices. The wire that generates the magnetic field could be a superconducting trace on a circuit that is routed next to the devices. The ∂V/∂B of the devices with respect to the magnetic field generated by the wire could be controlled by controlling the proximity of the device to the wire, controlling the size of the SQUID, or engineering secondary structures that influence the way that the flux from the wire couples into the SQUID. One example of a secondary structure that couples flux into a SQUID is a planar loop that shares an edge with the SQUID, but that is much larger than the SQUID.

FIG. 13 shows a voltage vs magnetic field for SQUIDs with different effective areas. SQUIDs that are different sizes will have different effective areas, so for the same magnetic field they will have different amounts of magnetic flux passing through the SQUID. Thus, SQUIDs with different effective areas will have different voltage responses as a function of the applied magnetic field. A larger SQUID will have a quicker period in its voltage vs. magnetic field than a small SQUID.

If the FLL and processing electronics for multiple SQUIDs are identical, but the SQUIDs have different effective areas, a SQUID with the higher ∂V/∂B will saturate with a smaller change in the magnetic field than a SQUID with smaller ∂V/∂B. It is possible to engineer SQUIDs with specific ∂V/∂B by changing the SQUID's effective area or by changing the coupling of the signal into the SQUID by moving the SQUID with respect to the signal source. Using these techniques, it is possible to design SQUIDs to measure a portion of the signal with a desired resolution, or to design a SQUID that can coarsely measure the entire signal without saturating at all.

According to one embodiment, flux focusing structures may also be added and configured to modify the effective area of a SQUID. A SQUID with a larger effective area, and a quicker period in its voltage vs. magnetic field response, will have portions of its voltage response that are steeper than the voltage response of a SQUID with a smaller effective area. This steepness can be expressed as a larger change in voltage for a change in magnetic field, denoted symbolically as ∂V/∂B. Restated, a SQUID with a larger effective area will have a higher possible ∂V/∂B than a smaller SQUID.

According to one embodiment, one or more SQUIDs may be engineered to achieve different sensitivities. In the dynamic range module 200, a low sensitivity SQUID can produce a coarse measurement of the input signal without saturating, while the more sensitive SQUID can produce fine measurements of the signal, but its processing electronics will saturate when the signal is larger than a threshold. When the electronics that process the output of the more sensitive SQUID saturates, its FLL is reset. Once the sensitive SQUID's FLL is reset, it will begin producing fine measurements again, but with an ambiguous offset with respect to the previous measurements. This ambiguity is resolved by the coarse measurements from the low sensitivity SQUID.

In this way, the low sensitivity SQUID provides measurements of the most significant bits (MSBs) of the signal, while the high sensitivity SQUID provides measurements of the least significant bits (LSBs) of the signal, and the overall dynamic range is divided into two separate channels.

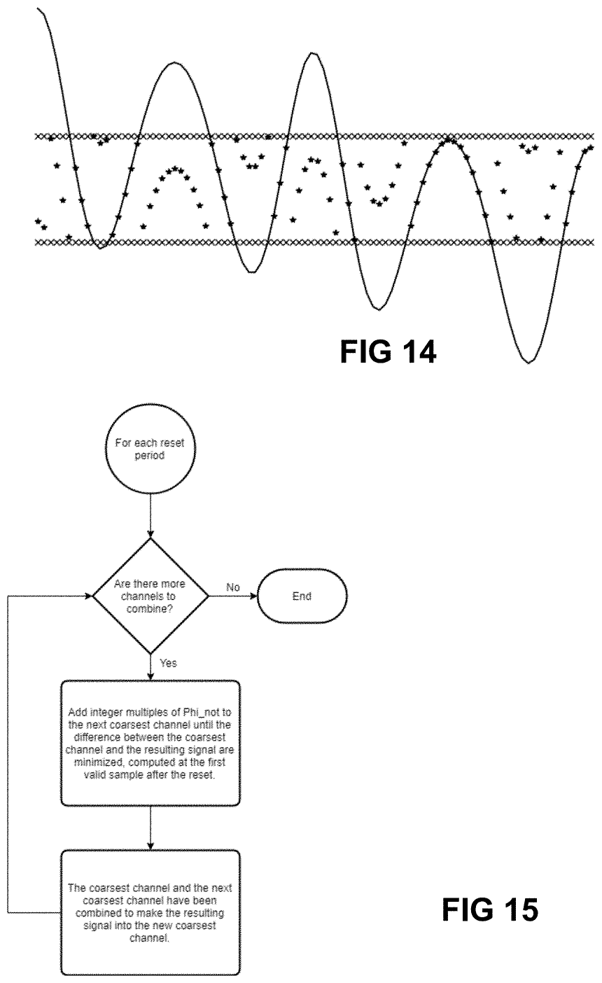

FIG. 14 shows an input field to the SQUID and output of the FLL together, according to one embodiment of the present disclosure. Here, the solid line is the input, the stars are the FLL output, and the cross hatched lines are the minimum and maximum boundary voltage that the FLL outputs.

FIG. 15 is a process diagram of the combination of channels during reset periods. The FLL linearizes the output of the SQUID by providing flux to the SQUID that is the opposite polarity to the flux that the SQUID is sensing from its environment. Flux with the opposing polarity is generated by driving current through a conductor that is next to the SQUID, so that the flux that is generated by the conductor opposes the flux that is entering the SQUID that is generated by other sources. This maintains the flux that in entering the SQUID at a constant operating point. The voltage and current coming from the FLL are linearly proportional to the difference between the flux entering the SQUID from all other sources and the constant operating point.

When the voltage or current coming from the FLL reach a threshold, the FLL can be reset. When the FLL resets, the amount of flux entering the SQUID changes to a new operating point. This operating point will be an integer multiple of φ₀ away from the previous operating point, where φ₀ is the quantum of magnetic flux. When the FLL is reset, the new operating point will be the closest integer multiple of φ₀ to the flux from sources other than the FLL. Because the FLL generates a voltage and current that are linearly proportional to the difference between the flux entering the SQUID from all other sources and the constant operating point, and because resetting the FLL minimizes this difference, resetting the FLL also decreases the voltage and current coming from the FLL. In this way, the FLL will need to generate less voltage and current to oppose the external flux.

The FLL may also be reset at a deterministic rate, such as every 10 nanoseconds. In that case, if the flux from sources other than the FLL were not different from the operating point by more than half of φ₀, the operating point would not change. However, if the flux from sources other than the FLL were different from the constant operating point by more than half of a φ₀, the operating point would change to the φ₀ that is closest to the flux from sources other than the FLL.

After a reset occurs, a portion of time may be allowed to pass to allow the circuit to reach steady state, such as five nanoseconds. After that time passes, the circuit will be producing usable measurements of the signal.

The signal from multiple channels may be recombined to create a linear measurement of the signal that has extended dynamic range. The coarsest signal, that contains the most significant bits (MSBs) of the dynamic range, is used to provide an estimate of the amplitude of the magnetic flux. The next coarsest signal is a measure of the difference between the magnetic flux and the nearest integer multiple of φ₀. To recombine the two signals into a single signal with extended dynamic range, integer multiples of φ₀ must be added to the next coarsest signal until it minimizes the difference in between the resulting signal and the coarsest signal. Whenever the FLL is reset, the number of integer multiples of φ₀ that must be added to the next coarsest signal will change. In between resets, the number of integer multiples of φ₀ that must be added to the next coarsest signal will remain constant. The number of integer multiples of φ₀ that should be added is the number that minimizes the difference between the resulting signal and the coarsest signal at the first usable measurement that occurs after a reset.

When the signal is divided into more than two channels, reconstructing the signal is an iterative process. First the process described above is applied to the coarsest and next coarsest signal. Then the resulting signal assumes the role previously held by the coarsest signal, and integer multiples of φ₀ are added to the next-next coarsest signal to minimize the error in between the next resulting signal and the first resulting signal, as described above. This process repeats for each additional channel that is added.

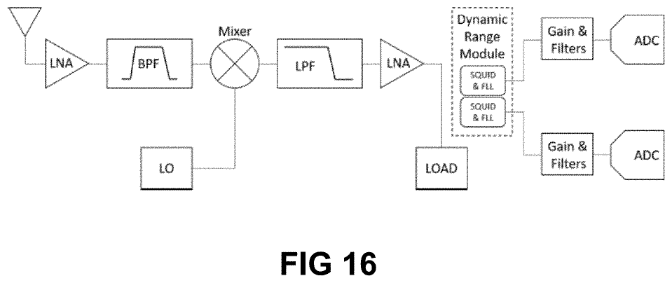

FIG. 16 schematically illustrates a dynamic range module in a radiofrequency receiver including two SQUIDs with FLL circuits. As shown, the dynamic range module can be inserted into an existing radiofrequency receiver to increase the receiver's dynamic range. A signal that has been mixed down to DC can be routed through a cable onto a chip that contains the dynamic range module. The SQUIDs in the dynamic range module then measure the magnetic field produced by the current from the signal. As described above, the SQUIDs then split the signal into separate channels composed different portions of the dynamic range.

The dynamic range module, consisting of the SQUIDs, their FLLs, and control circuitry, can be inserted into radios, radar, signals receivers (e.g., location/GPS, listening, spectrum sensing receiver, SW Defined Radio receiver, etc.), or test and measurement equipment, all as broadly understood.

After the signal is linearized by the FLL, it would be connected to processing components such as radiofrequency filters, gain stages, and an analog to digital convertor. The analog to digital convertor would send data to a processor, such as a field programmable gate array or microprocessor.

The SQUIDs are produced from a superconducting loop containing at least one Josephson Junction. They need to be cooled down below their critical temperature, which is the temperature at which they become superconducting. The cryogenic equipment to cool them down may consist of a cryocooler or a cryostat with a cooling mechanism, insulation system, and control system.

The SQUIDs must be shielded from magnetic fields that are not from the signal of interest. This can be done by placing a superconducting magnetic shield over them, or by configuring each SQUID as a gradiometer. A gradiometer SQUID cancels out any common mode signal, and could be configured to be sensitive to the magnetic field produced by the signal of interest.

SQUIDs are non-linear devices that can be used to divide the signal in a system into distinct channels, where each channel contains information about a different portion of the dynamic range of the signal. A DC SQUID is made from a superconducting loop that contains two Josephson Junctions (JJs). A JJ is a very thin break in the superconductor that allows a slight overlap in the electron pair wave functions between the two sides of the break. A lumped element model for a JJ, and for a DC SQUID, is shown in FIG. 1 and FIG. 2.

Generally, a radiofrequency front end may sense, amplify, filter, and perform other processing of a signal. The dynamic range module may be inserted into the radiofrequency front end at any point. After the dynamic range module, the signal is split separate channels, each with a different resolution, and each with a smaller total dynamic range than the signal before the module. The components in the circuit that follow the dynamic range module benefit from this reduction in dynamic range; they only need to handle the decreased dynamic range.

In that figure the dynamic range module has two SQUIDs and FLL circuits, which means that the dynamic range will be split into two channels. In this system the SQUID with the higher ∂V/∂B would make high resolution measurements over the lower portion of the dynamic range, and the SQUID with the lower ∂V/∂B would make coarse measurements over the upper portion of the dynamic range. The channels do not necessarily need to handle equal portions of the dynamic range, and it is possible that they would overlap a portion of their dynamic range.

A radiofrequency receiver with a dynamic range module as shown in FIG. 10 could be used to enable improved digital self-interference cancellation techniques in a radio with full duplex (FD) operation. By decreasing the dynamic range requirements of the components that follow the dynamic range module, a much larger dynamic range of signals can be digitized. Digitizing a broader portion of the dynamic range will allow more of the transmitted signal to be removed in the digital domain, which in turn will be important to increase the transmit power of FD radios.

The dynamic range module could also be used to allow radiofrequency receivers to continue to operate in the presence of other strong interferers, which would otherwise jam the radiofrequency receiver.

The dynamic range module could also be applied in RADAR signal processing chains. In RADAR, clutter can produce very strong reflections that can mask actual signals of interest. This can be exacerbated if the RADAR is trying to find small objects with very small signals. The use of a dynamic range module for RADAR will preserve the presence of small signals even with very large signals from other objects. This will allow the detection of objects with small signals in the presence of clutter or other larger objects.

If the dynamic range module is implemented using SQUIDs or other devices that rely on superconductivity, the superconducting portion of the system must be cooled in a cryostat, cryocooler, or other cryogenic system. The superconducting portion of the system might be cooled on a thermally conductive cold finger or by submersion into a cryogen such as liquid nitrogen or liquid helium. It would be thermally insulated from the environment, using insulator including but not limited to vacuum. A vacuum pump might be used to maintain the vacuum, or the vacuum chamber might be designed to maintain the vacuum for a long duration without additional pumping. The cryogenic system would include a capability to monitor the temperature of the superconducting system and to maintain the temperature at a desired level.

Other portions of the system may be implemented using superconducting components as well, including but not limited to low noise amplifiers (LNAs), mixers, low pass filters (LPFs), band pass filters (BPFs), high pass filters, notch filters, other radiofrequency filters, and ADCs. The antenna could be implemented using a superconducting trace, or it could be implemented using a SQUID or array of SQUIDs as a magnetic field sensor. If the antenna is implemented using a SQUID, it might include an FLL to linearize its output. Some components may be cryogenically cooled even if they are not superconducting to improve their noise characteristics.

It is possible to have multiple dynamic range modules in series to further increase the dynamic range of the system. In this arrangement, one or more of the channels that come from the first dynamic range module in the circuit would feed another dynamic range module. Each additional dynamic range module would further partition the dynamic range into smaller spans. In this way many dynamic range modules could be placed in series, forming a tree-like structure.

A magnetic shield could be used to attenuate undesirable magnetic field signals from the environment. Otherwise these signals will be sensed by the SQUIDs and incorporated into each of the channels. The use of shielding would also serve to attenuate the Earth's magnetic field. A magnetic field shield could be fashioned from superconductor. Undesirable signals could also be attenuated by configuring the SQUIDs to act as a gradiometer, which senses only the gradient in the magnetic field and attenuates the common mode signal.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention. The foregoing method descriptions and steps are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are simply used to guide the reader through the description of the methods.

The above description of the various embodiments is provided to enable a person of ordinary skill in the art to make or use the subject matter of the disclosure. Various modifications to the embodiments will be readily apparent to those skilled in the art, and the generic principles defined herein may be applied to other variations without departing from the spirit or the scope of this disclosure. However, any skilled person in the field of the art of the present disclosure may be able to make modifications not described in the present application. Notwithstanding, if these modifications require a structure or manufacturing process not described in the present disclosure, the modifications should be understood to be within the scope of the disclosure. Thus, it is to be understood that the disclosure is not intended to be limited to the examples and designs described herein, which merely represent a presently preferred implementation of the disclosure, but that the disclosure is to be accorded the widest scope consistent with the principles and novel features disclosed herein. It is to be further understood that the scope of the present disclosure fully encompasses other embodiments that may become obvious to those skilled in the art.

1. A dynamic range module for a signal receiver, the signal receiver having an analog front end including a signal carrying conductor and a signal processing back end, the dynamic range module comprising:
a superconducting quantum interference device (SQUID) configured to sense magnetic fields created by an electric signal travelling along the signal carrying conductor, said electric signal having combined together at least a weaker analog signal at a first power level and a stronger analog signal at a second power level, the SQUID further configured to output a SQUID output signal having a voltage that is periodic with regard to a strength of the magnetic fields sensed, the SQUID having a critical temperature;
a cryogenic system configured to cool the SQUID to or below the critical temperature; and
linearization circuitry configured to produce a dynamic range module output signal having a voltage that is linearly proportional to strength of the magnetic fields sensed by the SQUID, and further configured to communicate the dynamic range module output signal to the signal processing back end of the signal receiver.

2. The dynamic range module of claim 1, wherein signal processing back end of the signal receiver has a minimum and maximum boundary voltage, and the weaker analog signal at the first power level and the stronger analog signal at a second power level together result in at least a portion of an input field from the signal carrying conductor of the analog front end that extends beyond at least one of the minimum and maximum boundary voltage; and
wherein the dynamic range module output signal is within the minimum and maximum boundary voltage, and includes the portion of the input field from the signal carrying conductor of the analog front end that extends beyond at least one of the minimum and maximum boundary voltage.

3. The dynamic range module of claim 2, wherein the linearization circuitry includes a feedback loop configured to convert a non-linear output signal of the SQUID into a linear output signal via a magnetic field generator configured to generate a counteracting magnetic flux opposite the magnetic fields sensed by the SQUID.

4. The dynamic range module of claim 3, wherein the linearization circuitry further includes switching operable as an engage/disengage switch configured to reset the feedback loop at a predetermined rate or when the dynamic range module output signal is within a predetermined proximity of the minimum and maximum boundary voltage.

5. The dynamic range module of claim 3, wherein the SQUID includes a plurality of SQUIDs, each with different effective areas;
wherein the linearization circuitry includes a dedicated feedback loop and dedicated switching configured to engage/disengage said dedicated feedback loop, for each of one or more of the plurality of SQUIDs; and
wherein the dynamic range module output signal includes a plurality of a flux locked loop outputs (FLL outputs) communicated over a plurality of channels, from each of the plurality of SQUIDs, respectively.

6. The dynamic range module of claim 5, wherein one of the plurality of SQUIDs is configured as a coarse SQUID having its dedicated feedback loop, said coarse SQUID being sized sufficiently small to sense an entirety of the magnetic fields created by an electric signal travelling along the signal carrying conductor without resetting its dedicated feedback loop, said dedicated feedback loop configured to communicate a coarse FLL output over a coarse channel to the signal processing back end; and
wherein signal processing back end is configured to use the coarse FLL to reconstruct decoupled FLL outputs from other channels.

7. A signal receiver comprising:
an analog front end including a signal carrying conductor;
a signal processing back end having a minimum and maximum boundary voltage;
a superconducting quantum interference device (SQUID) configured to sense magnetic fields created by an electric signal travelling along the signal carrying conductor, said electric signal having combined together at least a weaker analog signal at a first power level and a stronger analog signal at a second power level, the weaker analog signal at the first power level and the stronger analog signal at a second power level together resulting in at least a portion of an input field from the signal carrying conductor of the analog front end that extends beyond at least one of the minimum and maximum boundary voltage, the SQUID further configured to output a SQUID output signal having a voltage that is periodic with regard to a strength of the magnetic fields sensed, the SQUID having a critical temperature;
a cryogenic system configured to cool the SQUID to or below the critical temperature; and
linearization circuitry configured to produce a dynamic range module output signal having a voltage that is linearly proportional to strength of the magnetic fields sensed by the SQUID, the dynamic range module output signal being within the minimum and maximum boundary voltage, the dynamic range module output signal including the portion of the input field from the signal carrying conductor of the analog front end that extends beyond at least one of the minimum and maximum boundary voltage, the linearization circuitry further configured to communicate the dynamic range module output signal to the signal processing back end of the signal receiver.

8. The signal receiver of claim 7, wherein the linearization circuitry includes a feedback loop configured to convert a non-linear output signal of the SQUID into a linear output signal via a magnetic field generator configured to generate a counteracting magnetic flux opposite the magnetic fields sensed by the SQUID.

9. The signal receiver of claim 8, wherein the linearization circuitry further includes switching operable as an engage/disengage switch configured to reset the feedback loop at a predetermined rate or when the dynamic range module output signal is within a predetermined proximity of the minimum and maximum boundary voltage.

10. The signal receiver of claim 9, wherein the signal carrying conductor is electrically coupled to the signal processing back end, and is configured to conduct the electric signal from analog front end to the signal processing back end.

11. The signal receiver of claim 10, wherein the analog front end includes an antenna configured receive electromagnetic signals and convert said electromagnetic signals into the electric signal.

12. The signal receiver of claim 11, further comprising a transmitter; and
wherein the antenna may receive electromagnetic signals transmitted by the transmitter.

13. The signal receiver of claim 9, wherein the SQUID includes a plurality of SQUIDs, each with different effective areas, one or more of said plurality of SQUIDs each including a dedicated feedback loop and dedicated switching configured to engage/disengage said dedicated feedback loop.

14. The signal receiver of claim 13, wherein one of the plurality of the SQUIDs is configured as a coarse SQUID having its dedicated feedback loop, said coarse SQUID being sized sufficiently small to sense an entirety of the magnetic fields created by an electric signal travelling along the signal carrying conductor without resetting its dedicated feedback loop, said dedicated feedback loop configured to communicate a coarse FLL output over a coarse channel to the signal processing back end; and
wherein signal processing back end is configured to use the coarse FLL to reconstruct decoupled FLL outputs from other channels.

15. A transducer system comprising:
an analog front end including a signal carrying conductor;
a signal processing back end having a minimum and maximum boundary voltage;
a superconducting quantum interference device (SQUID) configured to sense magnetic fields created by an electric signal travelling along the signal carrying conductor, said electric signal having combined together at least a weaker analog signal at a first power level and a stronger analog signal at a second power level, the weaker analog signal at the first power level and the stronger analog signal at a second power level together resulting in at least a portion of an input field from the signal carrying conductor of the analog front end that extends beyond at least one of the minimum and maximum boundary voltage, the SQUID further configured to output a SQUID output signal having a voltage that is periodic with regard to a strength of the magnetic fields sensed, the SQUID having a critical temperature;
a cryogenic system configured to cool the SQUID to or below the critical temperature; and
linearization circuitry configured to produce a dynamic range module output signal having a voltage that is linearly proportional to strength of the magnetic fields sensed by the SQUID, the dynamic range module output signal being within the minimum and maximum boundary voltage, the dynamic range module output signal including the portion of the input field from the signal carrying conductor of the analog front end that extends beyond at least one of the minimum and maximum boundary voltage, the linearization circuitry further configured to communicate the dynamic range module output signal to the signal processing back end of the signal receiver.

16. The transducer system of claim 15, wherein the linearization circuitry includes
a feedback loop configured to convert a non-linear output signal of the SQUID into a linear output signal via a magnetic field generator configured to generate a counteracting magnetic flux opposite the magnetic fields sensed by the SQUID, and
switching operable as an engage/disengage switch configured to reset the feedback loop at a predetermined rate or when the dynamic range module output signal is within a predetermined proximity of the minimum and maximum boundary voltage.

17. The transducer system of claim 16, wherein the SQUID includes a plurality of SQUIDs, each with different effective areas, one or more of said plurality of SQUIDs each including a dedicated feedback loop and dedicated switching configured to engage/disengage said dedicated feedback loop.

18. The transducer system of claim 17, wherein one of the plurality of the SQUIDs is configured as a coarse SQUID having its dedicated feedback loop, said coarse SQUID being sized sufficiently small to sense an entirety of the magnetic fields created by an electric signal travelling along the signal carrying conductor without resetting its dedicated feedback loop, said dedicated feedback loop configured to communicate a coarse FLL output over a coarse channel to the signal processing back end; and
wherein signal processing back end is configured to use the coarse FLL to reconstruct decoupled FLL outputs from other channels.
